(19) United States
(12) Patent Application Publication
(10) Pub. No.: US 2008/0237587 A1
(43) Pub. Date: Oct. 2, 2008

(54) Method and circuit for stressing upper level interconnects in semiconductor devices

(75) Inventors: Klaus Nierle, Essex Junction, VT (US); KoonHee Lee, South Burlington, VT (US)

Correspondence Address: POSZ LAW GROUP, PLC, 12040 SOUTH LAKES DRIVE, SUITE 101, RESTON, VA, 20191, US

(73) Assignee: Qimonda North America Corp., Cary, NC (US)

(21) Appl. No.: 11/730,222

(22) Filed: Mar. 30, 2007

(51) Int. Cl. H01L 23/58

(52) U.S. Cl. 257/48; 257/E23.141

(57) ABSTRACT

A device or method for effectively stressing an interconnect in a test current path of a semiconductor device, which test current path is other than a current path used during normal operation of the semiconductor device. An operational voltage is adjusted to a test voltage, the test current path is opened and the test voltage is supplied to the test current path.

### BACKGROUND

Defects and failures occur during the manufacture of semiconductor devices. A “failure” occurs when a semiconductor device fails to meet specifications. A “defect” occurs when a semiconductor device has an improper circuit structure that currently presents a failure of the device, or has the potential to cause failure during the expected lifetime of the device. Defects can occur in interconnects that are arranged between conductive layers within a semiconductor device. A defect in interconnects may not occur when the semiconductor device is produced, but such a defect has the potential to fail (e.g., short) during the expected lifetime of the semiconductor device.

During manufacture of semiconductor devices, voids are formed during the deposition of the necessary layers on a substrate, which include interconnects. As circuit density on semiconductor devices increases, the size of interconnects becomes smaller. A void in smaller interconnects is more likely to cause a short during the life expectancy of the semiconductor device. Such a short can cause an open circuit or a reduced voltage within the semiconductor device, and thus results in failure of the semiconductor device.

With the advent of Very Large Scale Integration (VLSI), many integrated circuit designs include several circuit functions on a single semiconductor substrate, such as memory storage and logic components for addressing and accessing the memory. In the case where a logic region and a dynamic random access memory (DRAM) are formed on the same substrate, the circuitry is commonly referred to as an embedded DRAM. In a DRAM, a plurality of conductor layers can be arranged above the actual memory cell array. One of these conductor layers can be connected to the WL-on potential and another connected to the WL drive circuit. Interconnects are arranged between these conductor layers, allowing the precharge of the WL-on potential to charge the word lines of the memory cells. Interconnects can also be used between the bit lines of DRAM.

Functional problems caused by voids in the upper level interconnects on DRAM containing semiconductor devices occur in certain instances at a very late state of the product life time and can not easily be detected or effectively stressed during semiconductor manufacturing. This is the case for the word line (WL) drive wiring, because the capacitive load of the WL is not large enough to establish a stress current which is sufficiently high to aggravate the marginality of the current path of the WL drive circuit.

Testing is performed on semiconductor devices to identify defects and failures. A conventional approach to testing interconnects involves operating the DRAM word line control in a nominal fashion while elevating the internal voltages by executing of a series of word line activate-precharge sequences. However, this approach only has a very limited effect on marginal connections, such as interconnects. This past approach is not suitable for aggravating or stressing defective connections to a level that results in an open circuit or unacceptably reduced voltage and that is easily detected during a following product testing.

### SUMMARY

A device or method for effectively stressing an interconnect in a test current path of a semiconductor device, which test current path is other than a current path used during normal operation of the semiconductor device. An operational voltage is adjusted to a test voltage, the test current path is opened and the test voltage is supplied to the test current path.

### BRIEF DESCRIPTION OF THE DRAWINGS

The accompanying figures, where like reference numerals refer to identical or functionally similar elements and which together with a detailed description set forth herein are incorporated in and form part of the specification, serve to further illustrate various exemplary embodiments and to explain various principles and advantages in accordance with this application.

FIG. 1 is a block diagram showing test circuitry on a semiconductor chip including a memory cell array and conductive layers having conductive interconnects extending therebetween in accordance with an embodiment of this application.

FIG. 2 is a block diagram showing various components of the block diagram of FIG. 1 in more detail and identifying a typical stress path including an interconnect in accordance with an embodiment of this application.

FIG. 3 is a flow diagram illustrating a procedure for stressing interconnects on a semiconductor chip in accordance with an embodiment of this application.

### DETAILED DESCRIPTION

The following exemplary embodiments and aspects thereof are described and illustrated in conjunction with structures and methods that are meant to be exemplary and illustrative, and not limiting in scope. In the following description, numerous specific details are set forth to provide a thorough understanding of the embodiments described in this application. In specific embodiments, circuits are shown in block diagram form in order not to obscure the embodiments described in this application in unnecessary detail. For the most part, details have been omitted inasmuch as such details are not necessary to obtain a complete understanding of the embodiments described in this application.

The embodiments of this application relate to a method and circuit for stressing interconnects formed between conductive layers in a semiconductor device. These embodiments include stressing interconnects contained within an array of dynamic random access memories (DRAMs), such as where interconnects that supply voltage to the word lines or bit lines of the memory array are arranged between conductive layers. These embodiments also include stressing interconnects arranged within any semiconductor device, such as those including logic components and memory storage devices other than DRAMs, for example, SDRAM (synchronous DRAM), SRAM (static random access memory), as well as stand alone RAM (random access memory). These embodiments further include stressing interconnects within VLSI devices where several circuit functions are provided on a single semiconductor substrate, such as memory storage and logic components for addressing and accessing the memory.

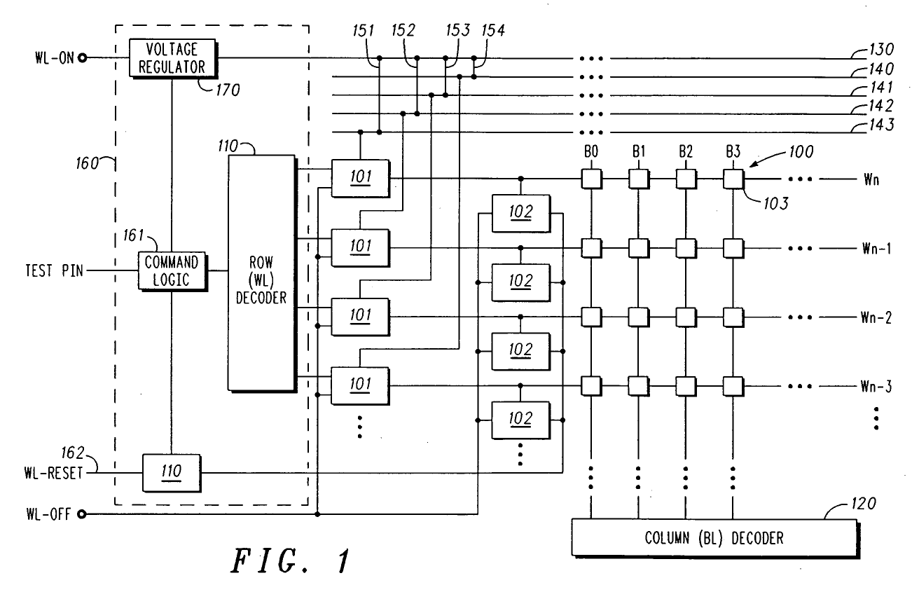

FIG. 1 represents a circuit diagram that includes a memory device 100, where a memory array is divided into word lines (WL) represented by horizontal lines and columns (or bit lines (BL)) represented by vertical lines. The word lines are identified by Wn, Wn−1, Wn−2 and Wn−3. The bit lines (BL) are identified by B0, B1, B2 and B3. Memory cells 103 memory cells are arranged at the intersection or crossover points of each of the word lines and bit lines. Only a few word lines, bit lines and memory cells are shown in FIG. 1, in order not to obscure the embodiments described in this application in unnecessary detail. While four word lines, four bit lines and 16 memory cells are shown, a larger number of word lines, bit lines and memory cells can be used, as understood by those skilled in the art, depending on the size and configuration of the memory array, as desired.

In the memory device 100 shown in FIG. 1, the memory cells 103 are selectively connected across the word lines Wn, Wn−1, Wn−2 and Wn−3 to WL on/off switches 101 and across the bit lines B0, B1, B2 and B3 to a column (BL) decoder 120. The WL on/off switches 101 are selectively connected to a word line-off (WL-off) potential (e.g., ground) and to a row (WL) decoder 110. In addition, the memory cells 103 are also selectively connected across the word lines Wn, Wn−1, Wn−2 and Wn−3 to the WL-off potential through WL reset switches 102. The WL on/off switches 101 are selectively connected across conductive layers 140, 141, 142 and 143 and interconnects 151, 152, 153 and 154 respectively to conductive layer 130, which in turn is connected to a word line-on (WL-on) potential through a voltage regulator 170.

In the embodiment of FIG. 1, each word line is supplied by one conductive layer 140, 141, 142, or 143 associated with one interconnect 151, 152, 153 or 154 for illustration purposes only. Although not shown, one conductive layer (i.e., one of 140, 141, 142 or 143) and a corresponding interconnect (i.e., one of 151, 152, 153 or 154) is typically associated with a plurality of word lines, such as four or more word lines.

While five conductive layers 130 and 140-143 and four interconnects 151-153 are shown, a larger number of conductive layers and interconnects can be used, as understood by those skilled in the art, depending on the size and configuration of the memory array, logic chips, etc., as desired. The conductive layers and interconnects can be made of doped polysilicon, doped amorphous silicon, germanium silicon, titanium nitride, a metallic material (such as an AlCu alloy), composites thereof, or a like conductive material.

The circuit shown in FIG. 1 further includes a test circuit 160 that can be added to the regular WL control to establish the control of the WL reset devices via an external control pin (not shown). The test circuit 160 controls the stressing of interconnects through a stress path that includes a word line (WL) driver circuit, which can include, for example, the conductive layer 130, one of the conductive layers 141-143, one of the interconnect 151-154, and one of the WL on/off switches and one of the word lines. In addition, the test circuit 160 includes command logic 161, the voltage regulator 170 and a WL-reset controller 10. When enabled, the test circuit 160 allows control of the WL precharge device (such as WL reset switches 102) by utilizing an external pin (not shown). The enabling of the WL precharge device by the test circuit 160 is not coupled with a discontinued or intermittent operation of the WL activate device, but rather results in a cross current from the WL voltage level (WL-on potential) to the WL-off potential to establish a current path for stressing the interconnect lines in the WL drive circuit. At the same time, the logic command 161 controls the voltage regulator to reduce the WL-on potential to a voltage WL-on voltage level to a level that avoids overstressing of the WL driver current path. For example, the voltage regulator 170 or other similar device reduces the WL-on potential from a nominal voltage (e.g., 2-4 V) to a test voltage of about 20 to 50% of the nominal voltage. The WL reset signal is either supplied by the WL control logic circuit or can alternatively be manipulated by an external pin when this test mode is activated.

The logic command 161 of the test circuitry can provide the necessary address and control signals to the row (WL) decoder 110 to properly activate a word line of the memory device 100. This includes sequentially or incrementally addressing word lines in a memory array. The logic command 161 also can provide a reset signal to the WL-reset controller 115 for resetting the word lines via the WL reset switches 102.

The test mode can be activated by a test control signal, such as a chip select signal, received on the test pin 162. The test pin 162 can be associated with pins on the semiconductor device other than the precharge pin and pins associated with word line operations. For example, the test pin 162 can be associated with the chip select pin, address pin, column address select (CAS), etc. When the test mode is enabled, the WL precharge device (such as WL reset switches 102) is controlled utilizing an external pin control. At the same time, the logic command 161 controls the voltage regulator 170 to reduce the WL-on potential voltage level to a level that avoids overstressing components within the WL driver current path other than the interconnect.

During test mode, the voltage regulator 170 supplies the test voltage to the stress path for a period of time A, which is independent of normal word line functioning. In other words, the WL precharge device is not coupled with timing limitations associated with normal word line operations during test mode, but rather can provide a cross current from the WL-on potential to the WL-off potential for a period of time A sufficient for stressing the interconnect lines in the WL drive circuit. The period of time A can be arbitrarily adjusted to a time sufficient for stressing the interconnect, while not damaging components of the memory device 100 within the stressing path other than the interconnect. In a typical stressing method, the test voltage is reduced to less than the nominal voltage, and the period of time A is increased to a time longer than that for normal word line operations.

FIG. 2 includes a more detailed diagram of some of the components shown in FIG. 1. These include the WL on/off switches 101, the WL reset switch 102 and the memory cells 103. The WL on/off switches 101 can include p-channel MOSFET (PFET) 201 and an n-channel MOSFET (NFET) 202 or other transistors and switching devices. When a selected WL on/off switch 101 receives a WL control signal from the row (WL) controller 110, it activates the word line associated therewith. The WL reset switches 102 includes an NFET 203 or other transistor and switching device arranged between the word line and the WL-off potential. When WL reset switches 102 are reset by receiving a WL reset signal from the WL-reset controller 115, all the word lines are reset or opened, thereby establishing a current path from the selected word line through the reset switch to the WL-off potential.

FIG. 2 also shows memory cell 103 including an array transistor 205 and a capacitor 206, as understood in the art. In addition, FIG. 2 shows a word line capacitor (parasitic capacitor) 204 connected to the word line. The word line capacitor is not shown in FIG. 1 for brevity.

A representative stress (or stressing) path is shown in FIG. 2 by arrows 221-229. Arrow 221 represents the stress path from the WL-on potential (and voltage regulator 170) along conductor 130, arrow 222 represents the current path across interconnect 151 and arrow 223 represents the current path along conductor 143. The stress path continues across the WL on/off switch 101, as shown by arrows 224 and 225, and along the word line, as shown by arrow 226. From the word line, the stress path continues through the WL reset switch 102, as shown by arrows 227 and 228, to the WL-off potential, as shown by arrow 229. As mentioned above, the voltage regulator 170 adjusts WL-on potential from a nominal value used for normal word line operations (e.g., read/write) to a voltage level that will not harm the components of the semiconductor device along the stress path. In the embodiment shown in FIG. 2, the components in the stress path in addition to the interconnect 151 include the WL on/off switch 1, such as a PFET 201 contained therein, and the WL reset switch 102, such as a NFET 203 contained therein.

In the embodiment illustrated in FIG. 2, a current path of normal operation includes that shown by arrows 221, 222, 223, 224, 225, 226 and 230, which are associated with the WL driver circuit that receives a precharge voltage. Another current path of normal operation includes that shown by arrows 226, 227, 228, 229, which are associated with a WL reset operation. A stressing or testing current path is shown by arrows 221-229 in FIG. 2. A current path common to the word line precharge operation and the stressed current path includes that shown by arrows 221-226. Along the current path shown by arrow 226, the stressed current path diverges at point 231 from the WL driver circuit toward the WL-off potential through the WL reset switch 102, thereby establishing the stressing current path (arrows 221-229). While a stressing current path is shown in FIG. 2 associated with a word line, those skilled in the art will understand that the arrangement shown in FIG. 2 could easily adapted to bit lines or other components that are powered by interconnects. A test circuitry for a bit line can include switches for activating bit lines, and switches for equaling or draining voltage on or from bit lines. An interconnect associated with a bit line can be stressed by precharging the current path to the bit line, and activating the bit line while equalizing or draining voltage on or from the bit line by appropriate switches.

A method of stressing an interconnect according to one embodiment can be summarized as follows:
1. Activate test mode for control of WL switches (transistors) via external pin (not shown) and lowering of WL-on voltage level,
2. Activate WL (X=0), and activate external pin controlling WL reset switches (transistors) for time period A,
3. After time period A has elapsed, the external pin controlling the WL reset switches (transistors) is deasserted (deactivated), making the WL reset switches (transistors) inactive again,
4. An external precharge command is applied to WL (X=0), and
5. Steps 2 and 3 are repeated for additional or all other word lines.

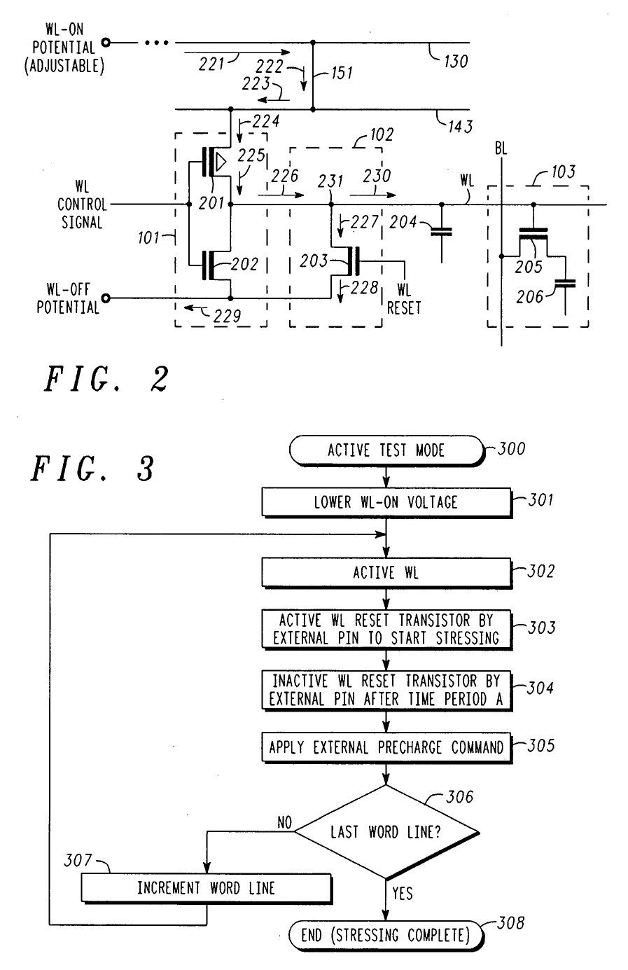

FIG. 3 is a flow diagram illustrating an embodiment for stressing interconnects on a semiconductor chip. When the logic command 161 receives the test control signal 162, the test mode is activated at 300. At 301, the WL-on potential is decreased to an acceptable voltage for stressing the interconnect, while not damaging other components in the current path. The word line is activated in 302 by, for example, the logic command 161 sending an appropriate signal to the row (WL) decoder 110. In 303, the WL-reset switches 102 are activated by an external pin, such as through a command initiated by logic command 161 to the WL-reset controller 115. In 304, after stressing the current path including the interconnect for a period of time A, the WL-reset switches 102 are deactivated by an external pin, such as through a command initiated by logic command 161 to the WL-reset controller 10. In, the WL reset switches 102 are deactivated, thereby ending stressing of the selected path identified by arrows 21-29 in FIG. 2. An external precharge command is applied in 305.

In 306, it is determined if the current word line is the last word line to be stressed. If no, the word line address is incremented to the next word line address in 307. From 307, the method returns to 302 for activating the next word line and stressing the path associated with the next word line including another or a different interconnect. If the answer in 306 is yes (the stress path of the last word line was competed), the method proceeds to 308 and ends. In a typical stressing method, all the word lines in the memory array will be individually and consecutively selected, so that interconnects associated with all the word lines are stressed.

In the embodiment shown in FIG. 3, while both selected WL on/off switch 101 and the WL reset switches 102 are activated for the period of time A in 303, a voltage less than the WL-on potential is applied to the interconnect associated with the selected word line. The cross current established during 303 effectively stresses the current path of the WL driver circuit and the interconnect associated therewith. By scaling the time period A, it is possible to find a good compromise between applying sufficient stress to the WL driver circuit and avoiding overstressing of the devices or circuits containing the interconnects. This procedure stresses a current path, such as that identified by arrows 21-29 in FIG. 2, with a voltage lower than that of the WL-on potential but for a period of time longer than a normal word line processing when the memory is used in a normal manner.

After the stressing of interconnects is complete, the semiconductor device can be tested by known methods to determine if any interconnects failed. For example, conventional testing of memory can be administered, where predetermined data or voltage values are applied to selected word line and bit line addresses, which correspond to certain memory cells to store or “write” data in the cells. Then, voltage values are read from such memory cells to determine if the data read matches the data written to those addresses. If the read data does not match the written data, then the memory cells at the selected addresses or interconnects associated therewith likely contain defects, and the semiconductor devices fail the test.

The foregoing description of the embodiments of the present invention is presented for purposes of illustration and description. It is not intended to be exhaustive or to limit the invention to the precise forms disclosed. Many variations and modifications of the embodiments described herein will be apparent to one of ordinary skill in the art in light of the above description. The scope of the invention is to be defined only by the claims appended hereto, as may be amended during the pendency of this application for patent, and all equivalents thereof.

Some embodiments can include a plurality of processes or steps, which can be performed in any order, unless expressly and necessarily limited to a particular order. As one of ordinary skill in the art would appreciate, other sequences of steps may be possible. Therefore, the particular order of the steps set forth in the specification should not be construed as limitations on the claims.

What is claimed is:

1. A semiconductor device comprising:
an interconnect connected between conductive layers, the interconnect being arranged within first and second current paths, an operating voltage flowing through the first current path during normal operations of the semiconductor device, and a test voltage flowing through the second current path during test operations for stressing the interconnect, and
a controller for switching between the first and second current path and for varying voltage within the second path between the normal voltage and the test voltage.

2. The semiconductor device according to claim 1, wherein
the first current path includes a first switch;
the second current path includes a second switch, the second current path including a part of the first current path, and the second switch intersecting the first current path at a point where the first and second current paths diverge;
the conductive layers include a first conductor layer that is connected to the first current path and a second conductor layer for providing the operating voltage;
the interconnect connects the first and second conductive layers;
during the normal operations, the controller:
opens the first switch and closes the second switch creating a current flow along the first current path; and
closes the first switch and opens the second switch creating a current flow along the second current path; and
during the test operations, the controller:
adjusts the operational voltage to a test voltage for stressing the interconnect;
opens the first and second switches creating a current flow along the second current path; and
closes the second switch after the interconnect stressing is complete.

3. The semiconductor device according to claim 2, wherein the semiconductor device comprises a memory device, wherein the first current path includes a word line that charges a memory cell, and the first switch activates the word line.

4. The semiconductor device according to claim 2, including a memory device, wherein the second switch of the second current path includes a word line reset switch.

5. The semiconductor device according to claim 2, including a memory device, wherein the first current path includes a bit line that reads a memory cell, and the first switch activates the bit line.

6. The semiconductor device according to claim 2, including a memory device, wherein the second switch of second current path includes a bit line reset switch.

7. The semiconductor device according to claim 1, wherein the test controller scales the test voltage to about 20%-50% of normal operating voltage.

8. The semiconductor device according to claim 1, wherein the test controller increases a time of stressing to a time period longer than normal timing for read/write operations.

9. A semiconductor device comprising:
a memory device including a memory cell, a word line and a bit line connected to the memory cell, and read/write circuits providing paths for storing a charge in the memory cell and reading the charge from the memory cell in normal operation;
first conductor layers providing a current path respectively to the word line and the bit line of the memory cell;
second conductor layers for providing an operating voltage;
an interconnect connecting the first and second conductive layers and selectively supplying the operating voltage to the word line and the bit line of the memory cell; and
a test circuit passing a test voltage through the interconnect, the test circuitry including a test path for the test voltage different from the read/write circuits in normal operation, whereby the interconnect is stressed by an amount more than an amount of stress during the normal operation.

10. The semiconductor device according to claim 9, wherein the test circuitry scales the test voltage to about 20%-50% of the operating voltage.

11. The semiconductor device according to claim 9, wherein the test circuitry passes the test voltage through the interconnect a period of time longer than that in normal read/write operations.

12. An on-chip test circuit for stressing a metal interconnect in a current path of a word line (WL) transistor and a reset transistor in a dynamic random access memory device, comprising:
a voltage regulator including an input for receiving an input WL reference voltage and a voltage scaler in communication with the WL transistor for scaling the WL reference voltage from a nominal value to a test mode value for activating the WL transistor, the test mode value being less than the nominal value;
an on-chip pin in communication with the reset transistor for receiving an external control signal to selectively activate the WL reset transistor for test mode purposes, wherein
a cross current flows across the metal interconnect through the WL transistor and the reset transistor as a result of both the WL transistor and the reset transistor being activated.

13. The on-chip test circuit of claim 12, wherein the test mode value of the WL reference voltage is between about 20%-50% of the nominal value.

14. The on-chip test circuit of claim 12, further comprising a controller for adjusting a time period during which the reset transistor is selectively activated to minimize stress on the WL transistor and the WL reset transistor.

15. The on-chip test circuit of claim 12, wherein the reset transistor is activated and deactivated by an external pin.

16. A method for stressing an interconnect within a current path in a semiconductor memory device, comprising:
scaling a reference voltage from a nominal value to a test mode value, the test mode value being less than the nominal value and sufficient to activate a switch along the current path;
passing the reference voltage through the interconnect and the current path;
activating a reset device for a testing period of time period based on an external control signal; and
generating a cross current on the current path and through the switch and the reset device as a result of the simultaneous activation of both the switch and the reset device.

17. The method for stressing an interconnect according to claim 16, wherein activating the switch activates a word line of a memory device.

18. The method for stressing an interconnect according to claim 16, wherein activating the switch activates a bit line of a memory device.

19. The method for stressing an interconnect according to claim 16, wherein the testing period of time is longer than a period of time for normal reading or writing of the memory device.

20. The method for stressing an interconnect according to claim 17, wherein a plurality of word lines and interconnects are sequentially stressed.

21. An on-chip test circuit for stressing an interconnect in a current path of a semiconductor memory device, comprising:
voltage means for receiving an input reference voltage and for scaling the input reference voltage from a nominal value to a test mode value, the test mode value being less than the nominal value;
path activating means for selectively activating and deactivating the current path;
path switching means for receiving an external control signal and activating and deactivating a reset device, the activated resent means diverting the current path into a test current path, wherein:
a cross current flows through the test current path containing the interconnect, the path activating means and the path switching means as a result of both the path activating means and path switching means being activated.

22. The on-chip test circuit according to claim 21, wherein the path activating means includes a word line activating device and the path switching means includes a word line reset device.

23. The on-chip test circuit according to claim 21, wherein the path activating means includes a bit line activating device and the path switching means includes a bit line reset device.

24. The on-chip test circuit according to claim 21, wherein the voltage means includes a voltage regulator.

25. The on-chip test circuit according to claim 21, wherein the input reference voltage is a word line precharge voltage, and voltage means reduces test mode voltage to about 20 to 50% of the nominal value of the precharge voltage.
